(19) United States
(12) Patent Application Publication
(10) Pub. No.: US 2019/0019704 A1
(43) Pub. Date: Jan. 17, 2019

(54) GLASS SUBSTRATE SHIPPER

(71) Applicant: ENTEGRIS, Inc., Billerica, MA (US)

(72) Inventors: Gary M. Gallagher, Austin, TX (US); Barry Gregerson, Excelsior, MN (US); Michael L. Johnson, Minneapolis, MN (US)

(21) Appl. No.: 16/076,820

(22) PCT Filed: Feb. 9, 2017
(86) PCT No.: PCT/US2017/017228

§ 371 Date: Aug. 9, 2018

Related U.S. Application Data
(60) Provisional application No. 62/303,643, filed on Mar. 4, 2016.
(60) Provisional application No. 62/293,240, filed on Feb. 9, 2016.

(51) Int. Cl. H01L 21/673

(52) U.S. Cl. CPC H01L 21/67386; H01L 21/67369; H01L 21/67346

(57) ABSTRACT

A substrate container (100) includes a base (105) and a cover (115). The cover (115) mates with the base (105) to define an enclosure. A stack of interlocking trays (405) can be disposed within the base (105). Each interlocking tray (405) includes an inset flange (410) defining a registration face (420) for supporting a substrate. The interlocking tray (405) also includes a shoulder portion (415). A relief feature (435) is defined at the junction point between the shoulder portion (415) and the registration face (420). The relief feature (435) may prevent the sharp edges of the substrate from contacting the shoulder portion (415), thereby reducing particle generation.

### CROSS REFERENCE TO RELATED APPLICATIONS

This application claims the benefit of U.S. Provisional Application No. 62/293,240 which was filed on Feb. 9, 2016 and U.S. Provisional Application No. 62/303,643 which was filed on Mar. 4, 2016, the entire contents of which are incorporated herein by reference in their entireties for all purposes.

### TECHNICAL FIELD

This disclosure relates generally to containers for storing and transporting substrates. More particularly, this disclosure relates generally to containers for storing and transporting thin glass substrates.

### BACKGROUND

It is important that containers for storing and transporting thin, fragile substrates, such as glass substrates, are designed to prevent the substrates from being damaged. Preferably, the containers, also known as shippers, are compact and designed to facilitate deposition of substrates therein and removal of substrates therefrom. In addition, it is beneficial for a given container to be able to safely transport different numbers and types of substrates. In view of the above, there is a need in the art for containers that meet these various criteria.

### SUMMARY

The present disclosure relates generally to substrate containers. In one illustrative embodiment, a container can include a base and a cover configured to mate with the base to define an enclosure. A tray stack can be disposed within the container and can include a plurality of interlocking trays disposed within the base, each of trays configured to receive and retain a substrate. The tray stack can have a height dimensioned for compression between the cover and the base portion, the compression exerting a clamping force on the tray stack when the cover is mated with the base. Additionally, each of the plurality of interlocking trays can include an inset flange having opposing sides, a first side of the opposing side defining a registration face and the second side of the opposing sides including a rib structure.

In another illustrative embodiment, a container can include a base having a bottom portion, a side wall extending upwards from the bottom portion and a rim portion extending radially outward from the side wall portion and a cover configured to mate with the base to define an enclosure. A tray is disposed within the base, the tray having a recessed portion configured to receive and retain one or more substrates. Additionally, the tray can include a bottom portion configured to support a substrate, a side wall portion extending upward from the bottom portion, and a rim portion extending radially outward from the liner side wall portion and configured to abut the rim portion of the base.

In yet another embodiment, a method includes placing a substrate on a registration face of a first interlocking tray, the first interlocking tray including an inset flange having opposing sides, a first side of the opposing side defining the registration face and the second side of the opposing sides including a rib structure; placing the first interlocking tray within a container having a base and a cover configured to mate with the base to define an enclosure; and placing a second interlocking tray on top of the first interlocking tray such that the second interlocking frame mates with a recessed corner defined by a shoulder portion of the first interlocking frame.

The preceding summary is provided to facilitate an understanding of some of the innovative features unique to the present disclosure and is not intended to be a full description. A full appreciation of the disclosure can be gained by taking the entire specification, claims, drawings, and abstract as a whole.

### BRIEF DESCRIPTION OF THE DRAWINGS

The disclosure may be more completely understood in consideration of the following description of various illustrative embodiments in connection with the accompanying drawings, in which:

FIG. 1 is an exploded view of a shipper including a tray in accordance with an embodiment of the present disclosure.

FIG. 2 is a perspective view of the shipper base and tray of the shipper of FIG. 1.

FIG. 3 is a perspective view of the bottom of the base of the shipper shown in FIGS. 1 and 2.

FIG. 4 is an exploded view of a shipper including a tray stack in accordance with another embodiment of the disclosure.

FIG. 5 is an exploded view of another shipper including a tray stack in accordance with yet another embodiment of the disclosure.

FIGS. 6A-6C show a tray and tray stack in accordance with an embodiment of the present disclosure.

FIG. 7 shows an assembled shipper utilizing the trays of FIGS. 6A-6C with substrates stored therein.

FIGS. 8A-8C the assembled shipper of FIG. 7.

FIGS. 9A-9C show a tray and a tray stack in accordance with yet another embodiment of the disclosure.

FIG. 10 shows a shipper having a base including finger reliefs in accordance with an embodiment of the present disclosure.

FIG. 11 is a perspective sectional view of a shipper utilizing a spacer in accordance with an embodiment of the present disclosure.

While the disclosure is amenable to various modifications and alternative forms, specifics thereof have been shown by way of example in the drawings and will be described in detail. It should be understood, however, that the intention is not to limit aspects of the disclosure to the particular illustrative embodiments described. On the contrary, the intention is to cover all modifications, equivalents, and alternatives falling within the spirit and scope of the disclosure.

### DESCRIPTION

As used in this specification and the appended claims, the singular forms “a”, “an”, and “the” include plural referents unless the content clearly dictates otherwise. As used in this specification and the appended claims, the term “or” is generally employed in its sense including “and/or” unless the content clearly dictates otherwise.

The following detailed description should be read with reference to the drawings in which similar elements in different drawings are numbered the same. The detailed description and the drawings, which are not necessarily to scale, depict illustrative embodiments and are not intended to limit the scope of the disclosure. The illustrative embodiments depicted are intended only as exemplary. Selected features of any illustrative embodiment may be incorporated into an additional embodiment unless clearly stated to the contrary.

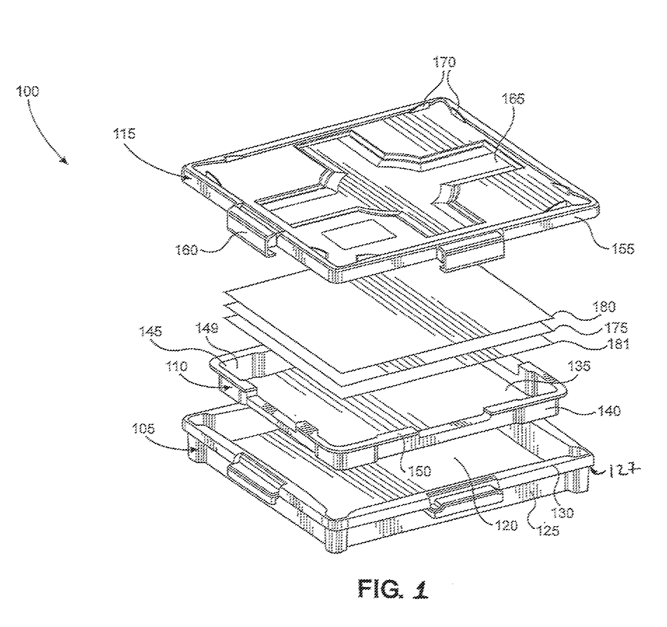

FIGS. 1- 3 show different views of a shipper or substrate container 100 according to an embodiment of the disclosure. The shipper 100 is configured to receive and retain at least one and more preferably, two or more thin substrates in a stacked configuration. One such substrate can be seen in FIG. 1. As shown in FIG. 1, a substrate 175 is located between interleaves 180 and 181, which are configured to separate substrate 175 from the bottom of shipper or a second substrate (not shown). In some embodiments, the shipper 100 is configured to receive and retain a plurality of thin, glass panels in a stacked configuration. In some cases, the glass panels or other substrates may have a rectangular shape, but other shapes are contemplated. The interleaves 180, 181 can be fabricated from a thin foam or film of varying thicknesses depending upon the application. In some embodiments, shipper 100 can include any number of spacers, compliant members (e.g. resilient foam inserts or cushions), interleaves, or other inserts to achieve a desired stack height within the shipper. Any combination of spacers, compliant members, interleaves, cushions, or other inserts can be used to accommodate substrates of varying thicknesses. In some embodiments, an RFID device can be integrated into shipper 100.

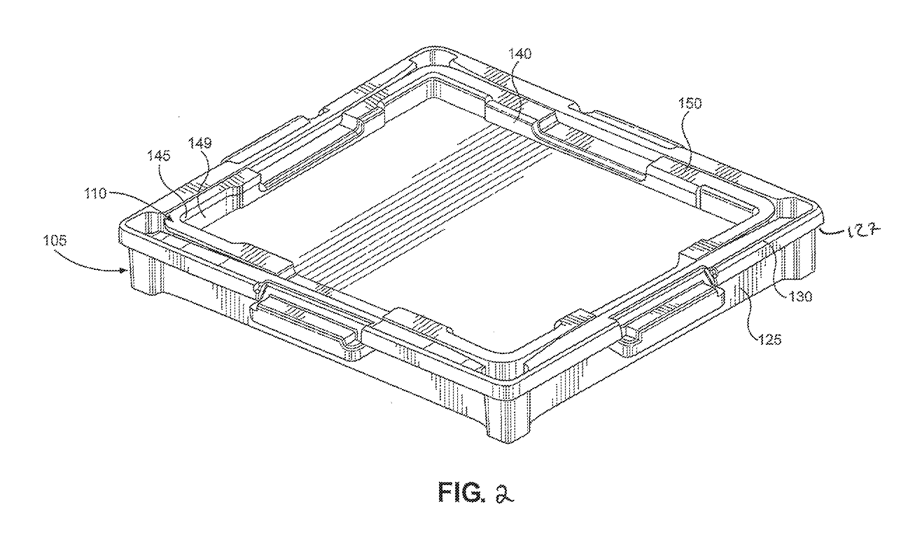

As shown in FIGS. 1 and 2, shipper 100 includes a base 105 configured to receive a stack of one or more one or more substrates, a tray 110 received within 105, and a cover 115 configured to mate with the base to define an interior of the shipper. Base 105 includes a bottom portion 120, a side wall portion 125 extending in an upward direction from the bottom portion 120, and a rim portion 130 extending radially outward from side wall portion 125 defining a lip 127. The lip 127 may be manually grasped by an operator during use for lifting and safe handling.

Tray 110 is received within base 105 and is configured to receive one or more substrates in a stacked configuration. Preferably, a stack of substrates is received within the tray. Tray 110 has a size and shape that is complimentary to the size and shape of the base 105, and includes a rectangular base portion 135, defining a planar interior surface, and a continuous side wall portion 140 extending upwards from base portion 135 and defining a perimeter of the tray 110. Side wall portion 140 includes planar sections that are perpendicular to the planar interior surface of base portion 135, which together define a tray depth. The tray depth can be defined as the distance from the planar interior surface to the upper most surface of the continuous sidewall portion 140. The tray depth may be selected such that any number of substrates, interleaves, foam inserts, or spacers may be received within the tray 110 and subsequently within the base. Side wall portion 140 also includes corners (one of which is labeled 145) that bridge adjacent ones of the planar sections, the corners protruding radially outward to define relief areas 149. A rim portion 150 extends radially outward from side wall portion 140 and is configured such that when tray 110 is received within the base 105, a lower surface of rim portion 150 of the tray 110 abuts an upper surface of rim portion 130 of the base 105.

Cover 115 is configured to mate with the base 105 to define an enclosure for housing the stack of substrates contained therein. In some cases, cover 115 is configured such that it fits over the outer rim 130 of the base 105. For example, as shown in FIG. 1, cover 115 can include a rim portion 155 configured to surround rim portion 130 of base 105. A plurality of latches (one of which is labeled 160) is configured to secure cover 115 to base 105, each of the latches being pivotally mounted to one of base 105 or cover 115. In the depicted embodiment, the latches are mounted to cover 115. Cover 115 also includes a recessed, contoured surface 165 for applying a compressive load to the contents of shipper 100 when cover 115 is coupled to base 105. The recessed, contoured surface 165 can have any number of sizes and shapes. In some embodiments, the recessed, contoured surface 165 is dimensioned and shaped generally corresponding to the size and shape of the substrates contained within the shipper 100. For example, in one embodiment, the recessed, contoured surface 165 can have a generally rectangular shape. In other embodiments, as shown, the recessed, contoured surface 165 has the general shape of a cross. The dimensions and shape of the recessed, contoured surface 165 are selected such that the recessed surface 165 transfers a compressive load to the contents of the shipper 100 and distributes the load more evenly across the substrates. In one embodiment, cover 115 may further include stacking features 170, proximate a perimeter thereof, configured to retain a corner of a second shipper stacked atop cover 115.

Functionally, the perpendicularity between the planar interior surface of tray 110 and the planar sections of side wall portion 140 provides alignment for a stack of substrates disposed in shipper 100. In some embodiments, the latches are over-center toggle type latches that create a high clamping pressure for ease of assembly. Contoured surface 165 of cover 115 can be configured to apply a downward compressive load to the resident substrates directly from the latching points. The relief areas 149 in the corners help prevent corner damage to rectangular substrates in transport and can provide a location for air separation of the resident substrates when being removed.

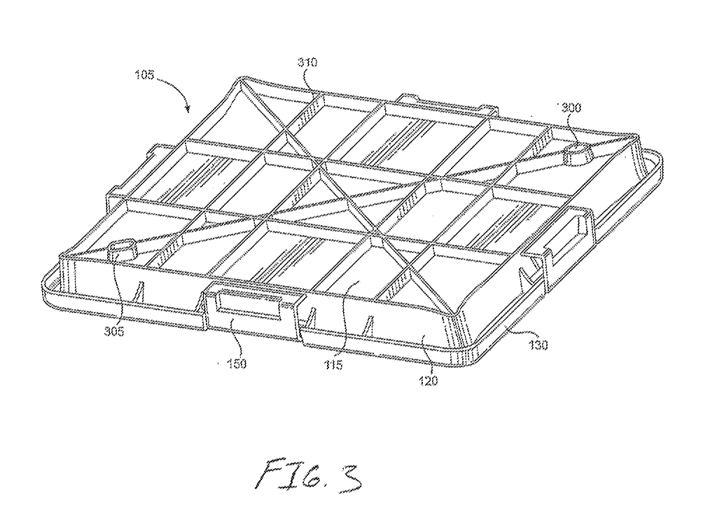

Referring now to FIG. 3, bottom portion 115 of base 105 may include one or more alignment features 300, 305 located on an exterior surface opposite the interior surface. The alignment features facilitate registration, alignment, or both automation equipment that may be used to interact with the shipper 100. The alignment features can have any size or shape that facilitates engagement and alignment with automation equipment. In some embodiments, as shown, the alignment features can include a recessed circular boss structure 300 and a recessed oval or rectangular boss structure 305, boss structures 300 and 305 extending axially from the exterior surface. In the depicted embodiment, oval boss structure 305 defines a major axis that is in substantial alignment with circular boss structure 300. The exterior surface can also be reinforced with ribbing 310 to create structure for maintaining the flatness of the interior surface. The alignment features 300, 305 or ribbing 310 may be integrally formed with the base 105 during manufacturing of the shipper 100.

In some embodiments, the tray 110 can be used as size adaptor to accommodate a plurality of trays having smaller dimensions than the container 100 is intended to accommodate. In this embodiment, tray 110 is received within the base 105 and a tray stack, such as tray stack 202, 400 or 400, as described herein, including a plurality of trays can be received within the tray 110.

Shipper 100 including one or more of base 105, tray 110 and cover 115 can be injection molded or thermoformed from a variety of thermoplastic materials suitable for the selected manufacturing method. In some cases, the shipper may be formed from an electrostatic dissipative material that dissipates any static charge build up on the outer surface of the container.

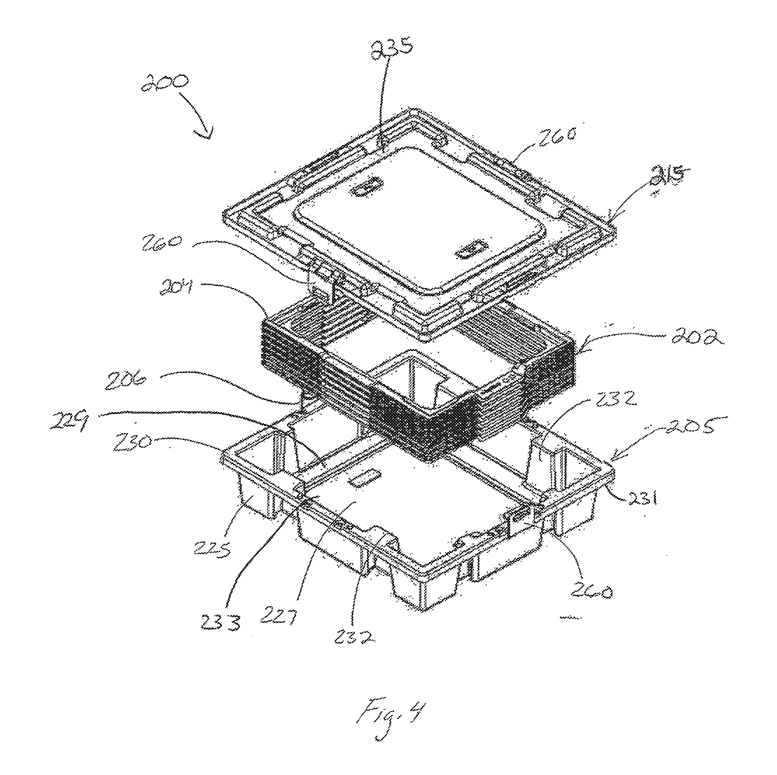

FIG. 4 shows a shipper 200 according to another embodiment of the disclosure including a plurality of individual trays 204 stacked upon one another defining a tray stack 202. Each individual tray 204 is configured to receive and retain a substrate thereon such at a plurality of substrates may be contained within the shipper 200. The size and shape of the individual trays 204 generally correspond to the size and shape of the substrates that the trays 204 are configured to retain. In one embodiment, the individual trays 204 forming the tray stack 202 are sized and shaped to retain a thin, rectangular glass panel thereon. While any number of trays is contemplated, the overall weight of the shipper 200 needs to be considered. As such the number of trays 204 forming the tray stack 202 can range from: 2 to 24; from 2 to 18; and from 2 to 12. In some embodiments, an RFID device can be integrated into each individual tray 204 to facilitate tracking of substrates on an individual basis.

Like shipper 100, shipper 200 includes a base 205 configured to mate with a cover 215 to define an enclosure. The base 205 includes a bottom portion 220 defining an interior planar surface 227 and a raised perimeter portion 229 surrounding the interior planar surface 227, a side wall portion 225 extending in an upwards direction from the bottom portion 220, and a rim portion 230 extending radially outward from side wall portion 225 that defines a lip 231 that may enable lifting and handling by an operator during use. In some embodiments, as shown, the side wall portion 225 can include one or more pairs of opposing protruding wall portions 232, which facilitate alignment of the plurality of trays 204 of the tray stack 202 within the base 205, and which may provide additional protection against shock events that may occur during shipping. Additionally, in some embodiments, a recess 233 may be defined between two protruding wall portions 232 located on the same side of the side wall portion 225. The recess 233 defined between two adjacent protruding wall portions 232 may provide an access point for automation equipment or a manual operator to access at least a portion of the tray stack 202 housed within the base 205 of the shipper 200. Preferably, a recess 233 is defined on each of the opposing sides of the side wall portion 224 of the base 205 to facilitate access to the tray stack 202 container therein.

Additionally, the base 205 has a depth that is defined as the distance from an upper surface of the raised perimeter portion 229 to the upper most surface of the rim portion 230. The depth of the base 205 may be selected such that it is configured to receive and retain a tray stack such as, for example, tray stack 202 having any number of trays, spacers, inserts, interleaves, resilient members, or combinations thereof defining a tray stack height, as necessary or desired. In some embodiments, the depth of the base 205 may be less than the overall height of the tray stack 202 such that at least a portion of the tray stack extends above an outer rim portion 230 of the base. In other embodiments, the depth of the base 205 may be substantially equal to the height of the tray stack 202.

In some embodiments, cover 215 can include a recessed portion 235. In some embodiments, the recessed portion 235 of cover 215 is dimensioned and shaped such that it generally corresponds to the dimensions and shape of the individual trays 204 forming the tray stack 202 housed within the shipper 200. In use, when the cover 215 is secured to the base 205, the recessed portion 235 of the cover 215 applies a compressive force to the tray stack 202 housed within the shipper 200. Selecting a recessed portion such that it dimensioned and shaped to generally correspond to the dimensions and shape of the individual trays 202 helps to more evenly distribute the load to the outer perimeter of the tray stack 202.

As can be seen in the embodiment depicted in FIG. 4, each of the base 205 and the cover 215 can include at least one pair of opposing latches 260. In some embodiments, the latches 260 are over-center toggle type latches that create a high clamping pressure for ease of assembly. Locating a first pair of latches on the cover 215 and a second pair of opposing latches on the base 205 helps to more evenly distribute the compressive forces over the entire tray stack 204 contained within the shipper 200.

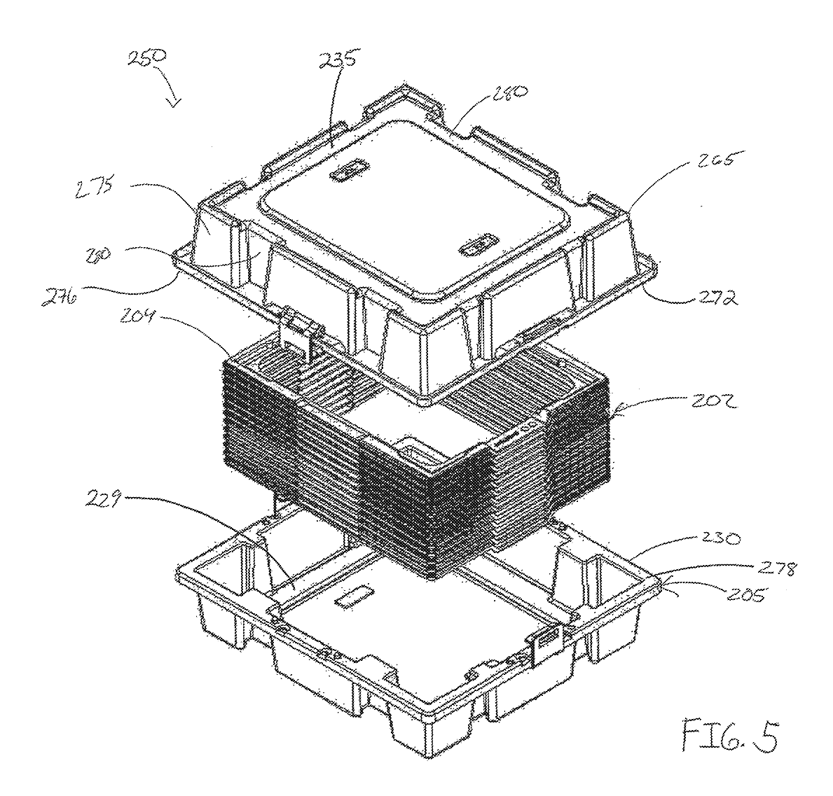

FIG. 5 depicts another shipper 250 according to yet another embodiment. In many aspects, shipper 250 has many of the same features as shipper 200, described herein. However, cover 265 of shipper 250 differs from cover 215 of shipper 210 in that cover 265 is dimensioned and sized to receive a least a portion of stackable tray system 202. Having a cover 265 that, like its corresponding base 205, is also sized to receive a portion of tray stack 202 allows for a larger tray stack having a greater number of trays 204 to be accommodated within the enclosure defined between the cover 265 and the base 205. In the embodiment depicted in FIG. 5, an overall height of tray stack 202 is greater than the depth of the base 205 such that the track stack 202 extends above an outer rim portion 230 of base 205.

In some embodiments, like base 205, described herein, cover 265 can include a side wall portion 275 can include one or more pairs of opposing protruding wall portions 280, which align the plurality of trays 204 of the tray system 202 within the base 205, and which may provide additional protection against shock events that may occur during shipping. Since base 205 remains the same for shipper 200 and shipper 250, cover 265 can be substituted for cover 215 to accommodate a greater number of trays 204, and consequently substrates, which may increase the overall versatility of shippers 200 and 250. Additionally, in some embodiments, the cover 265 and the base 204 can be configured such that a lower surface 272 of the outer rim portion 276 of the cover 265 abuts the upper surface 278 of the outer rim portion 230 of the base 230 when the cover 265 is mated to the base to define an enclosure.

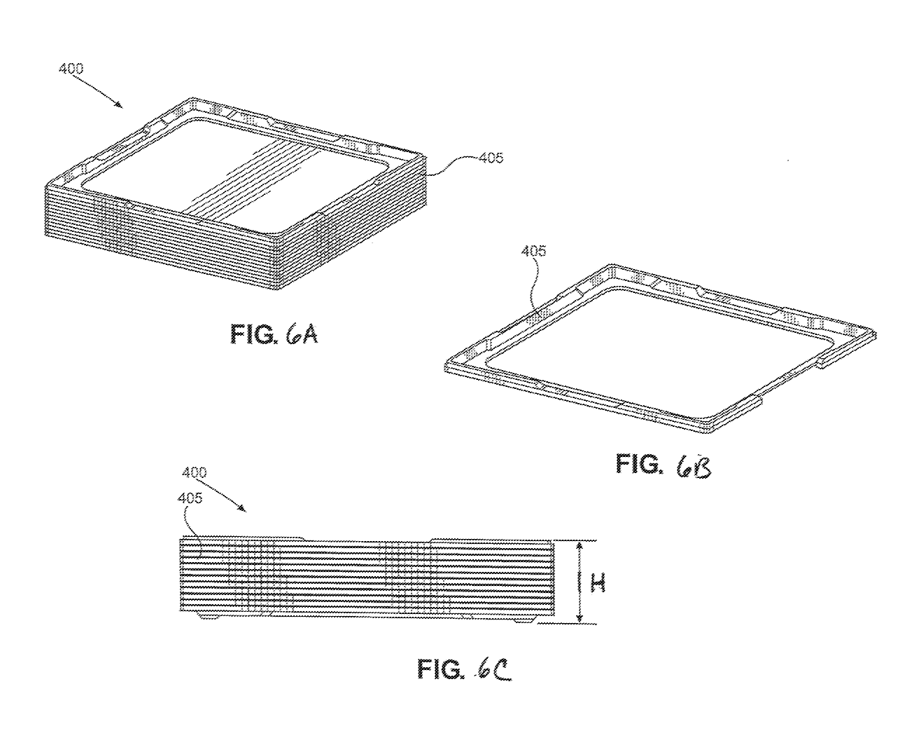

Referring now to FIGS. 6A-6C, FIG. 7, and FIGS. 8A-8C, a tray stack 402, according yet another embodiment, can include a plurality of interlocking trays (one of which is labeled 405) that cooperate with each other to define tray stack 400. The tray stack 400 can have an overall height H that is defined in part by the number and the thickness of each individual trays 405 forming the tray stack 400. The overall height H may be reduced by compressive forces exerted by the base and cover of a shipper, as described hererein, when the stack 400 is container therein.

Tray stack 400 is shown disposed in shipper such as, shipper 100. Each of the trays 405 includes an inset flange 410 and a shoulder portion 415. Inset flange 410 has opposing sides, a first of the opposing sides defining a registration face 420, and a second of the opposing sides including a rib structure 425. The registration face 420 is defined as an upper surface of the inset flange 410 on which a bottom of surface of a substrate is supported. In some embodiments, the registration face 420 contacts and supports a bottom of a substrate at the periphery of the substrate. The rib structure 425 is defined as a nub or protrusion that extends away from the second opposing side (lower surface) of the inset flange 410 and contacts an upper surface of a substrate supported by an adjacent tray at its periphery. In some embodiments the rib structure 425 is continuous about the perimeter of the tray 420. In other embodiments, the rib structure 425 is one of a plurality of discrete protrusions located at different locations along the second opposing side (lower surface) of the inset flange 410 of the tray 404. In one embodiment, as shown, the rib structure 425 has a rounded or curved surface which contacts an upper surface of a substrate at its periphery.

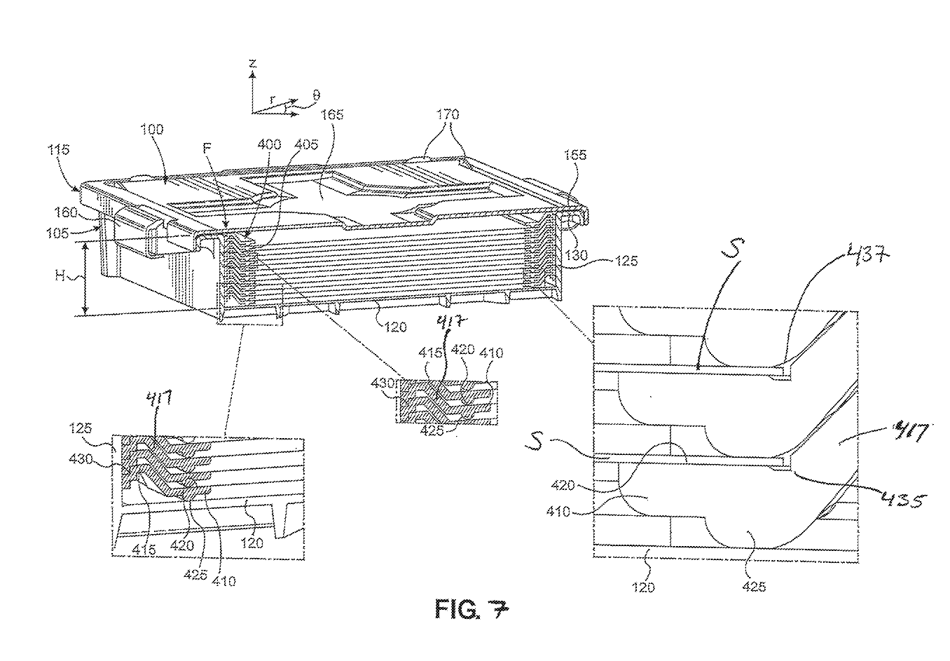

Shoulder portion 415 extends axially (i.e., in the z-direction of the r-θ-z coordinate system of FIG. 5) and radially outward from registration face 420 of inset flange 410. Shoulder portion 415 defines a recessed corner 430 at a peripheral extremity of the frame. In some embodiments, shoulder portion 415 can be configured such that an adjacent tray of the stack 400 mates with recessed corner 430, as depicted in FIG. 7. Additionally, the rib 425 of the adjacent tray of the stack cooperates with registration face 420 to define a gap therebetween. The gap is dimensioned so that, when a substrate is disposed therein, the opposing surfaces of the substrate contact the rib and registration face 420. Additionally, in a preferred embodiment, a corner relief 435 is defined at a junction between a downwardly extending leg 417 of shoulder portion 415 and registration face 420 of inset flange 410. The curved portion of the rib structure 425 defines an additional relief feature 437. The corner relief 435 and relief feature 437 create sufficient space such that the sharp edges of the substrate S do not come into contact with the shoulder portions 425 of the trays, thereby reducing any particle generation which may occur as a result of friction or abrasion that may occur between the sharp edges of the substrates and the trays 405.

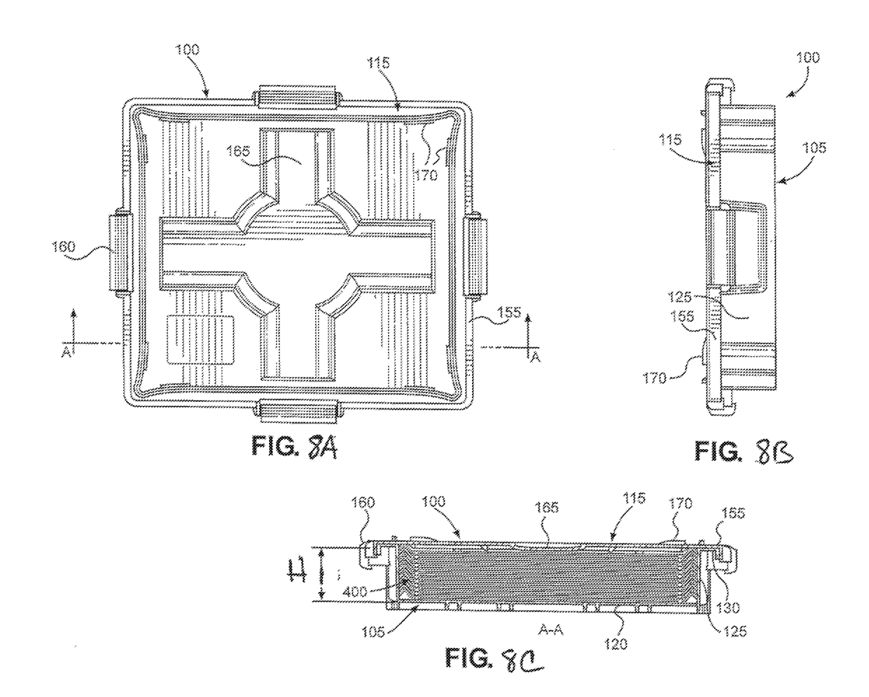

An internal height dimension H of shipper 100, as best seen in FIG. 8C is defined between an inside surface of cover 115 and an interior surface of base 105. In various embodiments, a tray stack, as described herein, is dimensioned to contact both the inside surface of cover 115 and the interior surface of base 105 for compression of the stack between cover 115 and base 105 to exert a force on the stack. Functionally, the compression exerts a force F on the stack, which translates to clamping forces that secure the resident substrates between the rib portions and registration faces of adjacent trays. The compression also captures air between the substrates, providing an air cushion that mitigates contact between resident substrates at the mid span due to shock or vibration.

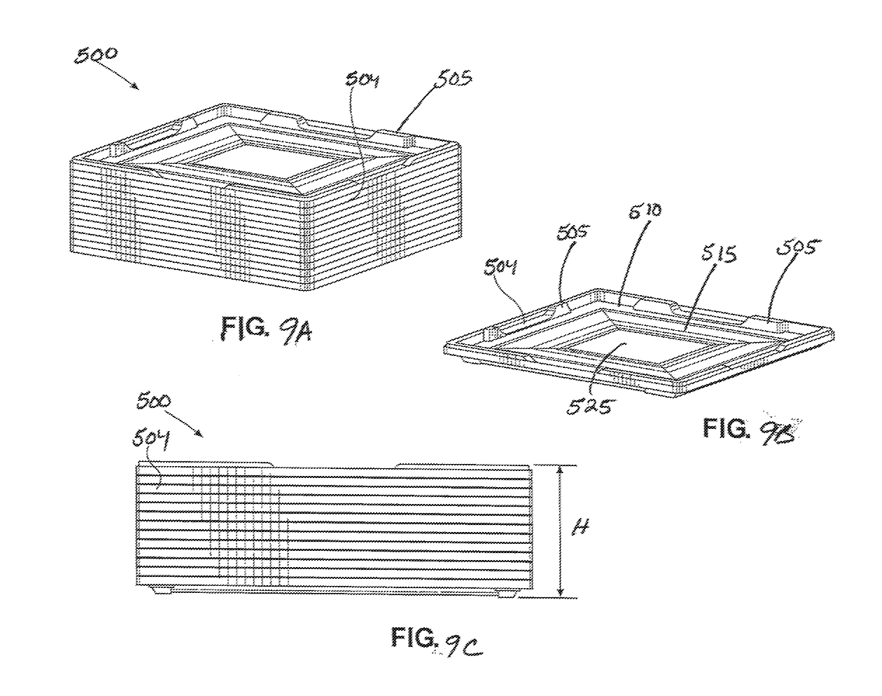

FIGS. 9A-9C show a tray stack 500 including a plurality of individual stackable trays 504 according to another embodiment. Tray stack 500 can be received and retained within a shipper such as, for example, shipper 100, shipper 200 or shipper 205, as described herein. As shown in FIGS. 9A-9C, tray stack 500 includes a plurality of interlocking features 505 distributed about a perimeter of each tray 504 that corporate with each other when at least a second tray is stacked upon a first tray to form the stack 500. Each of the trays 504 includes an inset flange 510 and a shoulder portion 515. Shoulder portion 515 extends downward at an angle from inset flange 510 to a solid, bottom panel 525. Together, inset flange 510, shoulder portion 515, and bottom panel 525 define a recessed portion which is sized and shaped to receive retain a substrate (not shown). The tray stack 500 has an overall height H that is defined in part by the number and the thickness of each individual trays 504 forming the tray stack 502. The overall height H can be reduced by compressive forces exerted by the base and cover of a shipper, as described hererein, when the stack 500 is container therein.

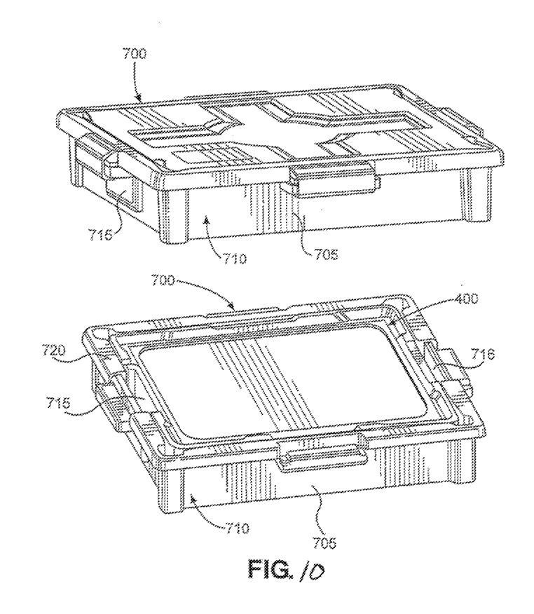

Referring to FIG. 10, a shipper 700 is depicted in accordance with an embodiment of the present disclosure. Shipper 700 is substantially identical to shipper 100 except that a side wall portion 705 of a base 710 of shipper 700 defines relief recesses 715 and 716 that extend through a rim portion 720 of base 710 for access to the stack of frame system 400.

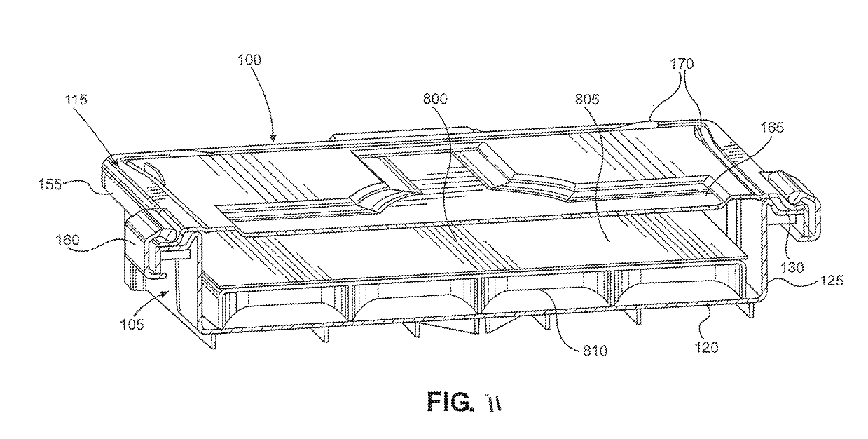

Referring to FIG. 11, shipper 100 is shown with a spacer 800 disposed therein in accordance with an embodiment of the present disclosure. Spacers enable stacks of different heights to be assembled within shipper 100 while still benefitting from the compression of the stack between cover 115 and base 105. Spacer 800 is mounted in base 105, and substrates (not shown) are mounted atop spacer 800. Spacer 800 is of a predetermined height or thickness based on the type of substrate that is shipped in shipper 100. In the depicted embodiment, a top surface 805 of spacer 800 is planar and a bottom surface 810 defines a cored structure. In some embodiments, spacer 800 includes structure for retaining a Radio Frequency Identification device (RFID).

Functionally, spacer 800 elevates the resident substrate stack (not shown) so that cover 115 engages the stack with a desired compressive force. Top surface 805 provides uniform support to the substrate stack. The cored structure provides the necessary structural stiffness while reducing material and weight of spacer 800. Because spacer 800 is unique to the thickness of the substrates to be stored in shipper 100, an RFID device can be programmed to convey information about the substrates being stored, including their thicknesses.

Although some of the drawings presented herein include dimensions, any dimensions included in the drawings are representative of certain embodiments and are not to be considered limiting.

Having thus described several illustrative embodiments of the present disclosure, those of skill in the art will readily appreciate that yet other embodiments may be made and used within the scope of the claims hereto attached. Numerous advantages of the disclosure covered by this document have been set forth in the foregoing description. It will be understood, however, that this disclosure is, in many respect, only illustrative. Changes may be made in details, particularly in matters of shape, size, and arrangement of parts without exceeding the scope of the disclosure. The disclosure's scope is, of course, defined in the language in which the appended claims are expressed.

What is claimed is:

1. A container comprising:
a base and a cover configured to mate with the base to define an enclosure; and
a tray stack comprising a plurality of interlocking trays disposed within the base, each of the plurality of interlocking trays having an inset flange having opposing sides, a first side of the opposing side defining a registration face and the second side of the opposing sides including a rib structure, each interlocking tray configured to receive and retain a substrate, and wherein the tray stack has a height dimensioned for compression between the cover and the base portion, the compression exerting a clamping force on the tray stack when the cover is mated with the base.

2. The container of claim 1, wherein the tray stack is placed under compressive forces when subjected to the clamping force exerted on the stack when the cover is mated with the base.

3. The container of claim 1, wherein each of the plurality of interlocking trays further comprises a shoulder portion extending axially and radially outward from the inset flange, the shoulder portion defining a recessed corner, wherein the shoulder portion is configured such that a first interlocking tray mates with the recessed corner of a second, adjacent interlocking tray.

4. The container of claim 1, wherein each of the plurality of interlocking trays further comprises a corner relief defined at the juncture between the registration face defined by the first opposing side of the inset flange and downwardly extending portion of the shoulder portion.

5. The container of claim 1, wherein the rib structure of a first interlocking tray is configured to cooperate with a registration face of a second, adjacent interlocking tray to define a gap therebetween, the gap being dimensioned so that, when a substrate is disposed therein, a first opposing side of the substrate contacts the rib structure and a second opposing side of the substrate contacts the registration face of the adjacent interlocking tray.

6. The container of claim 1, further comprising a latch configured to secure the cover to the base, wherein the latch is pivotally mounted to one of the base and the cover.

7. The container of claim 1, wherein the base comprises a first pair of opposing latches and the cover comprises a second pair of opposing latches.

8. The container of claim 1, further comprising at least one of spacer, insert, cushion, or compliant member.

9. The container of claim 1, the cover further comprising stacking features configured to retain a corner of a second container.

10. The container of claim 1, wherein each of the cover and the base include an outer rim portion, wherein the outer portion of the cover is sized to be received over and surround the outer rim portion of the base.

11. A container comprising:
a base having a bottom portion, a side wall extending upwards from the bottom portion and a rim portion extending radially outward from the side wall portion:
a cover configured to mate with the base to define an enclosure; and
a tray disposed within the base, the tray having a recessed portion configured to receive and retain one or more substrates, the tray including a bottom portion configured to support a substrate, a side wall portion extending upward from the bottom portion, and a rim portion extending radially outward from the liner side wall portion and configured to abut the rim portion of the base.

12. The container of claim 11, wherein the side wall portion of the tray includes planar sections and corners that bridge adjacent ones of the planar sections, the corners protruding radially outward to define relief areas.

13. The container of claim 11, wherein the cover includes a cover rim portion configured to be received over and surround the rim portion of the base.

14. The container of claim 11, wherein one of the cover or the base comprises at least one latch.

15. The container of claim 11, wherein the base comprises a first pair of opposing latches and the cover comprises a second pair of opposing latches.

16. The container of claim 11, wherein the side wall portion of the base defines a relief recess that extends through the base rim portion, the relief recess providing access to a substrate disposed within the substrate container.

17. A method comprising:
placing a substrate on a registration face of a first interlocking tray, the first interlocking tray including an inset flange having opposing sides, a first side of the opposing side defining the registration face and the second side of the opposing sides including a rib structure;
placing the first interlocking tray within a container having a base and a cover configured to mate with the base to define an enclosure; and
placing a second interlocking tray on top of the first interlocking tray such that the second interlocking frame mates with a recessed corner defined by a shoulder portion of the first interlocking frame.

18. The method of claim 17, wherein the first and second interlocking trays are part of a plurality of interlocking trays disposed within the container, the plurality of interlocking trays being arranged in a stack.

19. The method of claim 18, further comprising compressing the stack between the cover and the base, the compression exerting a clamping force on the stack.

20. (canceled) A method comprising:
inserting a tray within a container, the tray comprising a bottom portion, a side wall portion extending upward from the bottom portion and an outer rim portion and the container comprising a base portion, the base portion having a base bottom portion, a base side wall portion extending upwards from the base bottom portion and a base outer rim portion, wherein when the tray is inserted within the container, the outer rim portion of the tray abuts the outer rim portion of the base; and
placing a plurality of substrates within the tray.

21. (canceled)

22. (canceled)

23. (canceled)

24. (canceled)
